(19) United States
(12) Patent Application Publication
(10) Pub. No.: US 2026/0198243 A1
(43) Pub. Date: Jul. 9, 2026

(54) METHODS FOR WAFER LEVEL PROCESSING OF OPTICAL DEVICES WITH OPTICAL COATING EDGE INTEGRITY

(71) Applicant: VIAVI Solutions Inc., Chandler, AZ (US)

(72) Inventors: Alexis Weckel, Chandler, AZ (US); Georg Ockenfuss, Santa Rosa, CA (US); Hung Xuan Nguyen, Santa Rosa, CA (US)

(73) Assignee: VIAVI Solutions Inc., Chandler, AZ (US)

(21) Appl. No.: 19/313,719

(22) Filed: Aug. 28, 2025

Related U.S. Application Data
(60) Provisional application No. 63/742,842, filed on Jan. 7, 2025.

(51) Int. Cl. H01L 21/304; H01L 21/02

(52) U.S. Cl. CPC H10P 52/00; H10P 14/6542

(57) ABSTRACT

A method may include cutting a plurality of grooves partially through a thickness of a wafer substrate, where the plurality of grooves have a first width. The method may include applying an optical coating layer on the wafer substrate and over the plurality of grooves to obtain a wafer structure, where dicing streets for the wafer structure align with the plurality of grooves. The method may include dicing the wafer structure along the dicing streets using dicing cuts having a second width less than the first width.

### CROSS-REFERENCE TO RELATED APPLICATION(S)

This application claims the benefit of priority to U.S. Provisional Patent Application No. 63/742,842, filed Jan. 7, 2025, the disclosure of which is incorporated by reference herein in its entirety.

### BACKGROUND

Wafer level processing (WLP) includes techniques to package semiconductor devices at a wafer level, rather than at an individual die level. WLP integrates various fabrication steps (e.g., photolithography, etching, deposition, etc.) directly onto the wafer before it is diced into individual chips.

### SUMMARY

Some implementations described herein relate to an optical device. The optical device may include a substrate including a first surface, a second surface opposite the first surface, and a stepped edge extending between the first surface and the second surface, where the stepped edge defines a step surface. The optical device may include a niobium-based optical coating layer disposed on the first surface of the substrate. The niobium-based optical coating layer may extend over the step surface of the stepped edge.

Some implementations described herein relate to a wafer structure defining a plurality of optical devices. The wafer structure may include a wafer substrate having a plurality of grooves extending partially through a thickness of the wafer substrate. The plurality of grooves may align with dicing streets for the plurality of optical devices. The wafer structure may include an optical coating layer disposed on the wafer substrate and extending over the plurality of grooves.

Some implementations described herein relate to a method. The method may include cutting a plurality of grooves partially through a thickness of a wafer substrate, where the plurality of grooves have a first width. The method may include applying an optical coating layer on the wafer substrate and over the plurality of grooves to obtain a wafer structure, where dicing streets for the wafer structure align with the plurality of grooves. The method may include dicing the wafer structure along the dicing streets using dicing cuts having a second width less than the first width.

### BRIEF DESCRIPTION OF THE DRAWINGS

FIG. 1 is a perspective view of an example wafer structure.

FIG. 2 is a cross-sectional view of the example wafer structure of FIG. 1 taken along line A-A.

FIG. 3 is a perspective view of an example optical device.

FIG. 4 is a cross-sectional view of the example optical device of FIG. 3 taken along line B-B.

FIG. 5 is a flowchart of an example process associated with manufacturing an optical device with optical coating edge integrity.

FIG. 6 is an image of a diced wafer structure.

### DETAILED DESCRIPTION

The following detailed description of example implementations refers to the accompanying drawings. The same reference numbers in different drawings may identify the same or similar elements.

As described above, wafer level processing (WLP) includes techniques to package semiconductor devices at a wafer level, rather than at an individual die level. WLP integrates various fabrication steps (e.g., photolithography, etching, deposition, etc.) directly onto the wafer before it is diced into individual chips. For example, for optical devices, optical coating layers may be deposited on a wafer substrate before the wafer structure is diced to produce the individual optical devices. During dicing of the wafer structure, the optical coating layers on the wafer substrate may delaminate from each other and/or from the wafer substrate. “Delamination” may refer to peeling and/or chipping of optical coating layers from each other and/or from the substrate at an edge of an individual chip. This delamination affects the optical properties (e.g., refraction, diffraction, dispersion, transmittance, and/or reflectance, among other examples), and thus optical performance, of the optical devices, resulting in poor-performing devices and/or poor manufacturing yields.

Niobium-based optical coating layers are particularly sensitive to delamination. As a result, despite their desirable properties, niobium-based optical coating layers are generally avoided in WLP if high edge quality and/or dimensional precision of individual chips is needed. Due to the delamination issues associated with niobium-based optical coating layers, other inferior optical coating layers may be used instead. These other optical coating layers generally need to be applied at greater thicknesses, thereby increasing manufacturing time and material usage. Moreover, the other optical coating layers may be associated with high light angle shift, which may place excessive constraints on the range of characteristics that can be achieved in the optical devices.

Some implementations described herein relate to an optical device with optical coating edge integrity. The optical device may be achieved by employing a partial dicing step in WLP, whereby grooves are cut partially through a thickness of a wafer substrate before optical coating layer(s) (and in some cases, additional layers) are applied to the wafer substrate. The resulting wafer structure may be diced along the same paths as the grooves to produce a plurality of individual optical devices (e.g., chips).

Cutting the grooves into the wafer substrate may produce abrasions such that the grooves have a greater surface roughness than a remainder of the wafer substrate. This greater surface roughness and/or the contours of the grooves may provide improved adherence of optical coating layers to each other and/or to the wafer substrate during dicing of the wafer structure. Accordingly, the resulting individual optical devices after dicing may exhibit minimal or no delamination along their edges, thereby improving device performance and manufacturing yield.

Moreover, the optical devices may be produced using desirable optical coatings, such as niobium-based optical coatings, that are generally avoided or limited to use in more complex WLP techniques due to delamination issues. Thus, using these desirable optical coatings, the optical devices may have thinner blocking coatings (e.g., because the optical coatings provide higher refractive index ratios), thereby reducing manufacturing time (e.g., semiconductor fabrication machine time) and material usage. In addition, these desirable optical coatings may have less light angle shift, thereby allowing for a broad range of characteristics to be employed for the optical devices.

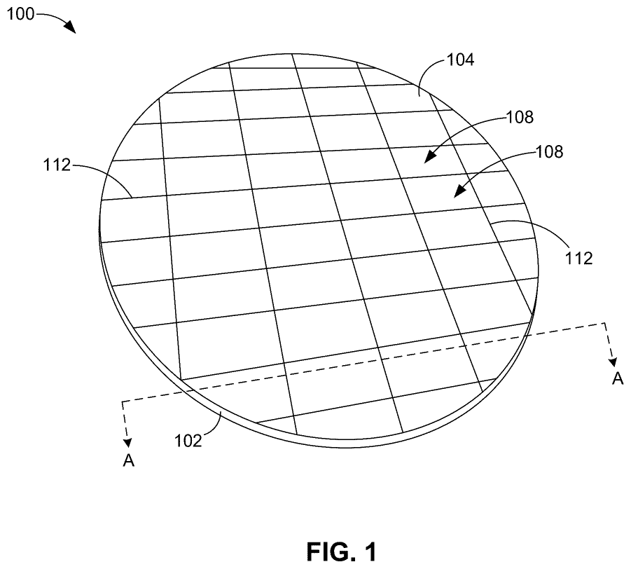

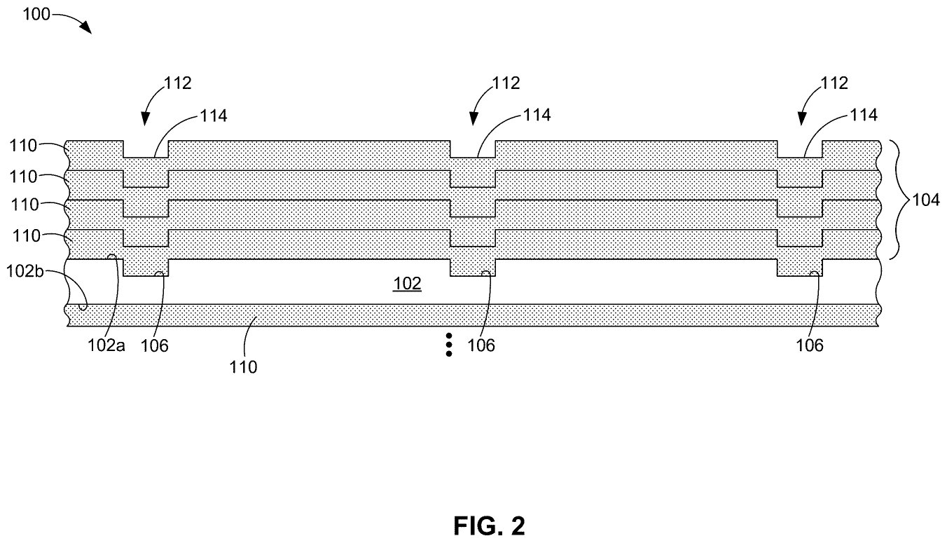

FIG. 1 is a perspective view of an example wafer structure 100, and FIG. 2 is a cross-sectional view of the example wafer structure 100 taken along line A-A.

The wafer structure 100 may include a wafer substrate 102. The wafer substrate 102 has a first surface 102a, and a second surface 102b opposite the first surface 102a. The wafer substrate 102 may support a layer structure 104 disposed on the first surface 102a of the wafer substrate 102.

The wafer substrate 102 may be composed of glass (e.g., fused silica, AF32, or the like), a semiconductor material (e.g., silicon, gallium arsenide, aluminum gallium arsenide, indium phosphate, or the like), or another type of material. The wafer substrate 102 may have a plurality of grooves 106 (e.g., valleys) that extend partially through a thickness of the wafer substrate 102 (e.g., at least 25%, at least 10%, at least 5%, or at least 2%, but not more than 50%, of the total thickness of the wafer substrate 102). For example, the grooves 106 may be present in the first surface 102a and extend toward, but short of, the second surface 102b. As an example, the wafer substrate 102 may be partially diced (e.g., using a saw, a laser, or the like) to form the grooves 106 prior to the application of the layer structure 104 on the wafer substrate 102, which allows the layer structure 104 to fill the grooves 106. The grooves 106 introduce contours (e.g., edges, facets, corners, etc.) into the wafer substrate 102 (which is otherwise substantially flat), thereby increasing surface roughness and surface area to achieve improved strength and adherence of the layer structure 104 during dicing. The grooves 106 may be arranged in a pattern of parallel lines, in a grid pattern, or in a pattern of non-intersecting ellipses (e.g., circles or ovals), among other examples. Elliptical grooves (e.g., circle or oval grooves) may be formed using a laser, and circular grooves in particular may be formed using a core drilling tool.

The layer structure 104 may include various semiconductor layers, dielectric layers, insulating layers, oxide layers, metal layers, and/or other layers for a plurality of optical devices 108 defined by the wafer structure 100. The optical devices 108 may include optical emitters (e.g., lasers, light emitting diodes, etc.), optical detectors (e.g., photodiodes, complementary metal-oxide-semiconductor (CMOS) sensors, etc.), optical filters, beam splitters, or beam combiners, among other examples.

The layer structure 104 may include an optical coating layer 110 (e.g., one or more optical coating layers 110). The optical coating layer 110 may be a niobium-based optical coating layer. For example, the optical coating layer 110 may be niobium titanium oxide (sometimes referred to as NbTiOx), niobium oxide, or another niobium-containing compound. As an example, the optical coating layer 110 may be Nb₂O₅, NbₓTi₍₁₋ₓ₎O_{y}, NbₓTa₍₁₋ₓ₎O₅, or NbₓM₍₁₋ₓ₎O_{y}, where 0<x<1 and where M is an oxide forming component. In some examples, the optical coating layer 110 may be a tantalum-based optical coating layer, such as tantalum oxide (e.g., Ta₂O₅) or another tantalum-containing compound. In other examples, the optical coating layer 110 may include (e.g., combined with niobium-based oxides) silicon dioxide (SiO₂), tantalum oxide (Ta₂O₅), silylidyne (SiH), aluminum oxide (Al₂O₃), silicon nitride, (Si₃N₄) or another type of material that has light transmission and/or reflection properties. The optical coating layer 110 may be, or may be a part of, a mirror, an anti-reflection coating, or the like, for the optical devices 108.

The optical coating layer 110 may be applied on the wafer structure 100 (e.g., on the wafer substrate 102) using a chemical vapor deposition (CVD) technique, a physical vapor deposition (PVD) technique, a molecular beam epitaxy (MBE) technique, or another technique. For example, the optical coating layer 110 may be applied on the wafer structure 100 using reactive pulsed direct current (DC) magnetron sputtering, radio frequency (RF) sputtering, alternating current (AC) sputtering, ion beam sputtering (IBS), electron beam (e-beam) evaporation, and/or thermal evaporation. In some implementations, one or more additional optical coating layers 110 may be disposed on the second surface 102b of the wafer substrate 102. For example, the additional optical coating layers 110 may include one or more tantalum oxide coating layers alternating with one or more silicon dioxide coating layers.

In some implementations, the layer structure 104 may include a single optical coating layer 110 (e.g., a niobium-based optical coating layer). In some implementations, the layer structure 104 may include multiple optical coating layers 110 (e.g., a niobium-based optical coating layer and a different optical coating layer), as shown. For example, the layer structure 104 may include a plurality of first optical coating layers 110 (e.g., niobium-based optical coating layers or tantalum-based optical coating layers) alternating with a plurality of second different optical coating layers 110 (e.g., silicon dioxide layers). The first optical coating layers 110 may have a different refractive index than a refractive index of the second optical coating layers 110. As described herein, the layer structure 104 may include other layers (e.g., semiconductor layers, dielectric layers, insulating layers, oxide layers, metal layers, and/or other layers) as needed to complete the optical devices 108.

The grooves 106 may be cut into the wafer substrate 102 in alignment with dicing streets 112 that will be used for the optical devices 108 (e.g., dicing of the wafer structure 100 may follow along the same paths as the grooves 106). The dicing streets 112 are narrow gaps between individual optical devices 108 (e.g., chips) of the wafer structure 100 where the wafer structure 100 will be diced, thereby producing the individual optical devices 108.

The grooves 106 may be cut into the wafer substrate 102 using a saw (e.g., a diamond saw), a laser, or another cutting implement. The grooves 106 may have a width that is wider than a width of the final dicing cuts for the wafer structure 100 (e.g., wider than a thickness of the saw used to make the final dicing cuts). As an example, the width of the grooves 106 may be in a range from 200 to 400 micrometers (μm), in a range from 250 to 350 μm, in a range from 280 to 320 μm, or approximately (e.g., +10%) 300 μm (e.g., the grooves 106 may be made with a blade width of 300 μm). A maximum depth of the grooves 106 may be in a range from 50 to 100 μm, in a range from 60 to 90 μm, or may be 50 μm or less, 20 μm or less, 10 μm or less, 5 μm or less, or 2 μm or less. Although the grooves 106 are shown as having a rectangular cross-section with well-defined corners, in practice, the grooves 106 may be rounded and sloping to their bottom point (e.g., parabolic shaped). The dicing cuts (e.g., a thickness of the saw used to make the dicing cuts) may have a width in a range from 40 to 60 μm, in a range from 50 to 60 μm, or in a range from 100 to 250 μm, or approximately 250 μm. The dicing cuts may have a width (e.g., a blade width used for the dicing cuts) that is narrower than a width of the grooves 106 (e.g., a blade width used to form the grooves 106), such as narrower by 50 μm or less, 20 μm or less, or 10 μm or less. In an example using laser cutting, the grooves 106 may have a width (e.g., a cutting width used to form the grooves 106) in a range from 10 μm to 20 μm, and a width of the dicing cuts (e.g., a cutting width used for the dicing cuts) may be 5 μm or less, or 1 μm or less.

The optical coating layer 110 is disposed on the wafer substrate 102 and extends over the grooves 106. For example, the optical coating layer 110 may fully or partially fill the grooves 106 (e.g., each groove may be fully or partially filled by the optical coating layer 110), or may be disposed on one or more other optical coating layers 110 that directly fill the grooves 106. As a result of the optical coating layer 110 extending over the grooves 106, the optical coating layer 110 may have a plurality of depressions 114 (e.g., dicing lanes) corresponding to the locations of the grooves 106 (e.g., the contouring of the grooves 106 may be carried up into the optical coating layers 110, such that the dicing lanes defined by the grooves 106 are still present after coating). In some implementations, the optical coating layer 110 may not have the depressions 114, depending on the depositional technique used to apply the optical coating layer 110.

Cutting the grooves 106 into the wafer substrate 102 may produce abrasions (e.g., a rough surface topography) such that the grooves 106 have a greater surface roughness (e.g., an average roughness in a range from 0.05 to 0.5 μm) than a remainder of the wafer substrate 102 (e.g., an average roughness of 2.0 nanometers or less, or 0.2 nanometers or less). This greater surface roughness and/or the contours of the grooves 106 (e.g., which are carried up into the optical coating layers 110) may promote adherence of the layer structure 104 during the dicing of the wafer structure 100. For example, the grooves 106 may define dicing lanes that are also present in the optical coating layers 110 after coating of the wafer substrate 102, and the dicing lanes in the optical coating layers 110 may also exhibit a greater surface roughness (e.g., at the bottoms of the dicing lanes).

Accordingly, an individual optical device 108 produced from dicing the wafer structure 100 may exhibit reduced delamination along an edge of the optical device 108. For example, an individual optical device 108 produced from dicing the wafer structure 100 may exhibit no delamination of the optical coating layers 110 that extends more than 25 μm, 10 μm, or 5 μm, from an edge of the optical device 108.

As indicated above, FIGS. 1-2 are provided as an example. Other examples may differ from what is described with regard to FIGS. 1-2.

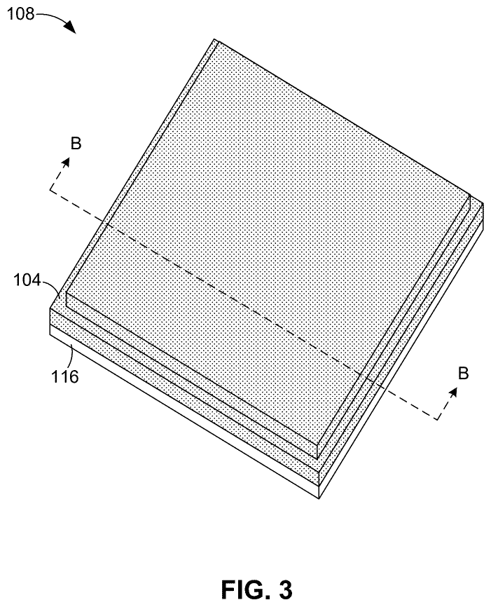

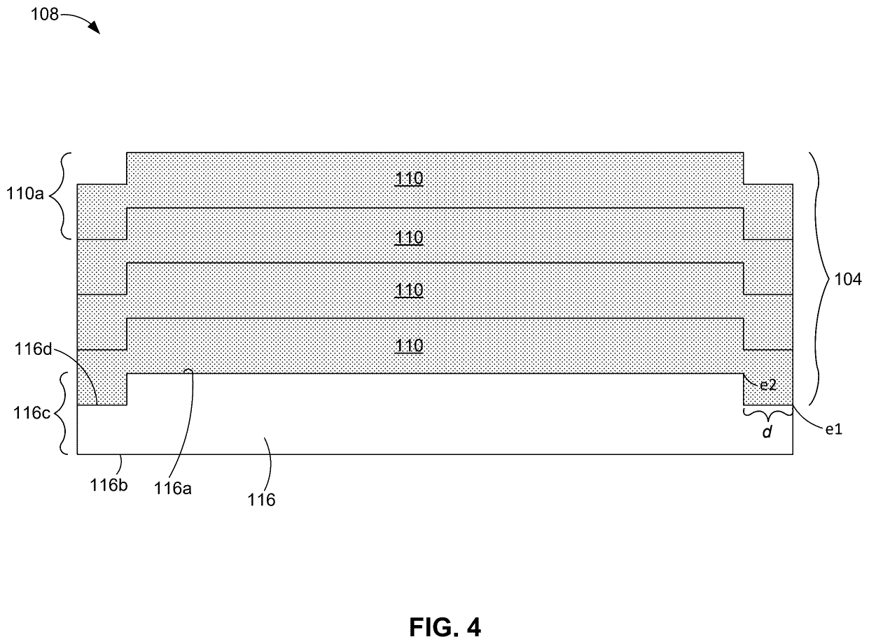

FIG. 3 is a perspective view of an example optical device 108, and FIG. 4 is a cross-sectional view of the example optical device 108 taken along line B-B. Dicing of the wafer structure 100 along the dicing streets 112 may produce the optical device 108 (as well as additional copies of the optical device 108). As shown, the optical device 108 may have an overall terraced shape (e.g., an upper terrace of lesser width upon a lower terrace of greater width) due to the partial pre-dicing of the wafer substrate 102.

The optical device 108 may include a substrate 116 (e.g., a diced portion of the wafer substrate 102). The substrate 116 has a first surface 116a, a second surface 116b opposite the first surface 116a, and a stepped edge 116c extending between the first surface 116a and the second surface 116b. In some implementations, the stepped edge 116c may extend around an entire circumference of the substrate 116. Alternatively, the stepped edge 116c may extend around only a portion of the circumference of the substrate 116.

The stepped edge 116c may be the result of the partial dicing of the wafer substrate 102 that forms the grooves 106, that is followed by a final, full dicing of the wafer structure 100 (e.g., along the same paths as the grooves 106) to singulate the optical device 108. The grooves 106 may have a width that is wider than a width of the dicing cuts used to fully dice the wafer structure 100, thereby resulting in the stepped edge 116c. For example, the grooves 106 may be partially cut into the wafer substrate 102 using a first saw, and the wafer structure 100 may be fully diced, along the grooves, using a second different saw having a lesser thickness than the first saw. The stepped edge 116c defines a step surface 116d. The step surface 116d may be an approximately flat surface of the stepped edge 116c, approximately parallel with the first surface 116a and the second surface 116b, extending from an end (labeled as e1 in FIG. 4) of the stepped edge 116c inward toward an edge (labeled as e2 in FIG. 4) of the first surface 116a. A lateral distance (labeled as d in FIG. 4) between the edge of the first surface 116a and the end of the stepped edge 116c, which may correspond to a depth of the step surface 116d, may be in a range from 10 to 70 μm, in a range from 40 to 60 μm, or in a range from 50 to 60 μm. Although the stepped edge 116c is shown with a well-defined rectangular step, in practice, the stepped edge 116c may have the form of a chamfer, bevel, or curve, and the step surface 116d may correspond to where the chamfer, bevel, or curve bottoms out.

The layer structure 104, including the optical coating layer 110, may be disposed on the first surface 116a of the substrate 116. Moreover, the optical coating layer 110 may overhang the first surface 116a of the substrate 116. For example, the optical coating layer 110 may extend over (e.g., above) the stepped edge 116c and over (e.g., above) the step surface 116d. As an example, the optical coating layer 110 may extend down the side of the stepped edge 116c and onto the step surface 116d. In some implementations, the optical coating layer 110 may extend over the stepped edge 116c and the step surface 116d around the entire circumference of the substrate 116. Alternatively, the optical coating layer 110 may extend over the stepped edge 116c and the step surface 116d around only a portion of the circumference of the substrate 116.

As a result of the optical coating layer 110 extending over the stepped edge 116c, the optical coating layer 110 may similarly have a stepped edge 110a with a step surface corresponding to the stepped edge 116c (e.g., the optical coating layer 110 deposited on the grooves 106 in the wafer substrate 102 may conform to the contours of the grooves 106 and thereby take on similar contours as the grooves 106, resulting in the optical coating layer 110 also having the stepped edge 110a after dicing). In some implementations, the optical coating layer 110 may not have the stepped edge 110a, depending on the depositional technique used to apply the optical coating layer 110.

The stepped edge 116c and the step surface 116d (as well as the stepped edge 110a) may have a surface roughness that is greater than a surface roughness of the first surface 116a or the second surface 116b of the substrate 116 (e.g., due to abrasions caused during the partial dicing of the wafer substrate 102). This greater surface roughness, in combination with the contouring of the stepped edge 116c of the substrate 116 and/or the stepped edge 110a of one or more optical coating layers 110, may provide improved adherence of the optical coating layer 110 to the substrate 116 and/or to other optical coating layers 110 such that there is minimal delamination along an edge of the optical device 108.

As indicated above, FIGS. 3-4 are provided as an example. Other examples may differ from what is described with regard to FIGS. 3-4.

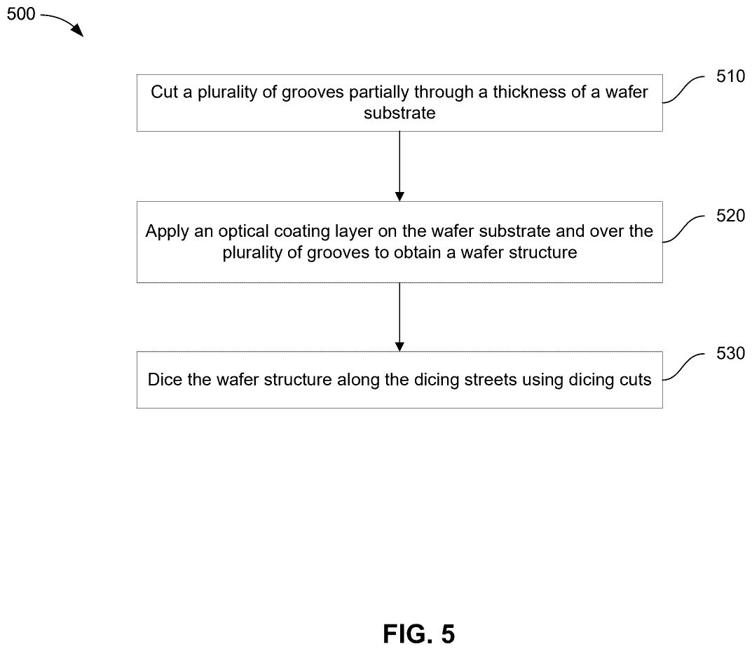

FIG. 5 is a flowchart of an example process 500 associated with manufacturing an optical device with optical coating edge integrity. The steps of process 500 may be performed by various semiconductor manufacturing equipment.

At step 510, process 500 may include cutting a plurality of grooves 106 partially through a thickness of a wafer substrate 102 (e.g., a glass wafer substrate). That is, partial dicing of the wafer substrate 102 may be performed prior to applying an optical coating layer 110 (e.g., a niobium-based optical coating layer) on the wafer substrate 102. The grooves 106 may be blade cut (e.g., using a diamond saw) or laser cut. The grooves 106 may have a first width (e.g., in a range from 200 to 400 μm). In some implementations, cutting the grooves 106 may produce abrasions (e.g., due to a roughness of the saw and/or due to making multiple parallel cuts with the saw to produce each groove 106) in the wafer substrate 102 having a first surface roughness greater than a second surface roughness of a surface of the wafer substrate 102.

At step 520, process 500 may include applying an optical coating layer 110 on the wafer substrate 102 and over the plurality of grooves 106 to obtain a wafer structure 100. That is, the optical coating layer 110 may be applied after the partial dicing of the wafer substrate 102. In some implementations, the optical coating layer 110 may be applied with one or more additional optical coating layers 110. In some implementations, additional layers, such as semiconductor layers, dielectric layers, insulating layers, oxide layers, metal layers, and/or other layers, may also be applied on the wafer substrate 102 (e.g., above, below, and/or in between the optical coating layer(s) 110) to complete the optical devices 108 defined in the wafer structure 100. Dicing streets 112 for the wafer structure 100 may align with the grooves 106 in the wafer substrate 102. For example, the dicing streets 112 may follow the same paths as the grooves 106.

At step 530, process 500 may include dicing the wafer structure 100 along the dicing streets 112 using dicing cuts. For example, the dicing cuts may be made in the grooves 106 (e.g., at approximately the centers of the grooves 106). The dicing cuts may have a second width (e.g., in a range from 50 to 60 μm) less than the first width of the grooves 106. For example, the wafer structure 100 may be diced using a saw having a lesser thickness than the first width of the grooves 106.

Although FIG. 5 shows example steps of process 500, in some implementations, process 500 may include additional steps, fewer steps, different steps, or differently arranged steps than those depicted in FIG. 5.

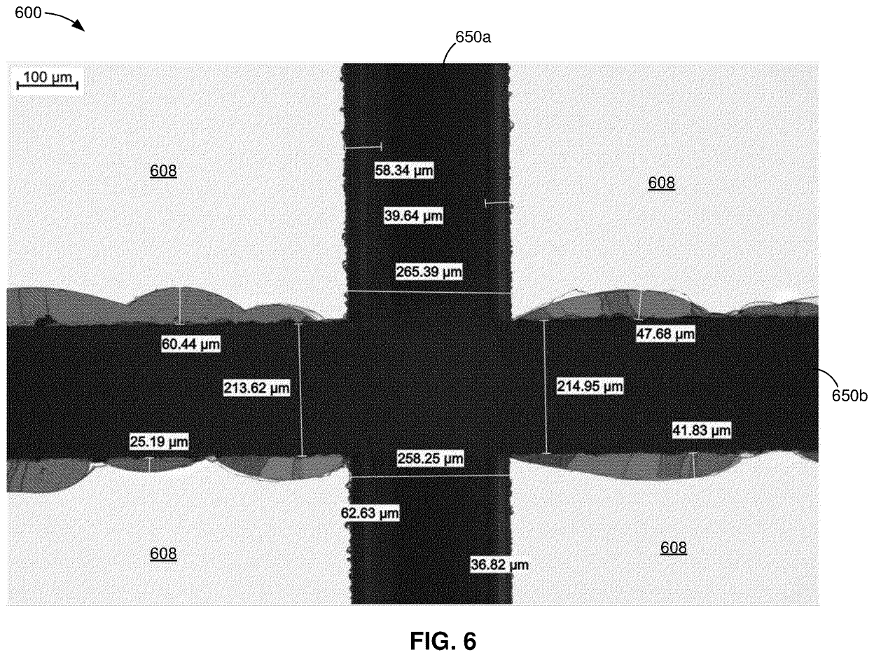

FIG. 6 is an image of a diced wafer structure 600. The wafer structure 600 may have the features of the wafer structure 100, described herein. In FIG. 6, the wafer structure 600 has been diced along a vertical dicing cut 650a and a horizontal dicing cut 650b to separate four optical devices 608 (e.g., having the features of the optical devices 108, described herein). Along the vertical dicing cut 650a, a wafer substrate of the wafer structure 600 was partially diced prior to coating with optical coating layers, whereas along the horizontal dicing cut 650b, the wafer substrate was not partially diced. As shown, along the vertical dicing cut 650a, the optical devices 108 have minimal edge delamination. For example, there is no delamination that extends more than 25 μm, 10 μm, or 5 μm, from the edges of the optical devices 608 along the vertical dicing cut 650a. However, along the horizontal dicing cut 650b, there is significant edge delamination, which extends more than 10 μm from edges of the optical devices 608 (e.g., up to 60 μm in some regions). Accordingly, the partial dicing technique described herein results in significantly less delamination along the edges of the optical devices 608. This result is further confirmed from the following experimental data.

### EXPERIMENTAL DATA

Tape testing was performed on a chip produced using the partial dicing technique described herein, and on a chip produced with conventional techniques and without using the partial dicing technique described herein. The tape testing was performed by adhering pieces of tape to the edge of the chips and removing the tape according to a slow removal methodology (after 24 hours of adherence), a quick removal methodology (after 48 hours of adherence), and a snap removal technology (after 10 days of adherence). A tape test was scored as passing if no optical coating residue was observed on the tape following removal, and was scored as failing if optical coating residue was observed on the tape following removal. The following table summarizes the tape testing results.

| | 49° Celsius (C.)/ | | |
|---|---|---|---|
| Environmental | 95% relative | 55° C./ | 85° C./ |
| Conditions | humidity (RH) | 95% RH | 85% RH |
| Duration | 24 hours | 48 hours | 10 days |
| Release | Slow | Quick | Snap |
| Chip with partial | Pass | Pass | Pass |
| dicing | | | |
| Chip without partial | Fail | Fail | Fail |
| dicing | | | |

The tape testing demonstrates that optical coating layers exhibit improved adherence at the edge of chips produced using the partial dicing technique described herein.

The following provides an overview of some Aspects of the present disclosure:

Aspect 1. An optical device, comprising: a substrate comprising: a first surface; a second surface opposite the first surface; and a stepped edge extending between the first surface and the second surface, wherein the stepped edge defines a step surface; and a niobium-based optical coating layer disposed on the first surface of the substrate, wherein the niobium-based optical coating layer extends over the step surface of the stepped edge.

Aspect 2. The optical device of aspect 1, wherein the niobium-based optical coating layer exhibits no delamination that extends more than 10 micrometers from an edge of the optical device.

Aspect 3. The optical device of any of aspects 1-2, further comprising a layer structure disposed on the first surface of the substrate, wherein the layer structure includes the niobium-based optical coating layer and a different optical coating layer.

Aspect 4. The optical device of any of aspects 1-3, further comprising a layer structure disposed on the first surface of the substrate, wherein the layer structure includes a plurality of niobium-based optical coating layers, that include the niobium-based optical coating layer, alternating with a plurality of different optical coating layers.

Aspect 5. The optical device of any of aspects 1-4, wherein the stepped edge extends around an entire circumference of the substrate.

Aspect 6. The optical device of aspect 5, wherein the niobium-based optical coating layer extends over the step surface of the stepped edge around the entire circumference of the substrate.

Aspect 7. The optical device of any of aspects 1-6, wherein a first surface roughness of the step surface is greater than a second surface roughness of the first surface.

Aspect 8. The optical device of any of aspects 1-7, wherein the niobium-based optical coating layer has a stepped edge corresponding to the stepped edge of the substrate.

Aspect 9. The optical device of any of aspects 1-8, wherein the optical device has a terraced shape.

Aspect 10. The optical device of any of aspects 1-9, wherein the niobium-based optical coating layer is niobium titanium oxide.

Aspect 11. The optical device of any of aspects 1-10, wherein the optical device is an optical emitter or an optical detector.

Aspect 12. A wafer structure defining a plurality of optical devices, the wafer structure comprising: a wafer substrate having a plurality of grooves extending partially through a thickness of the wafer substrate, wherein the plurality of grooves align with dicing streets for the plurality of optical devices; and an optical coating layer disposed on the wafer substrate and extending over the plurality of grooves.

Aspect 13. The wafer structure of aspect 12, wherein the plurality of grooves have a first width that is wider than a second width of dicing cuts to be used for the wafer structure.

Aspect 14. The wafer structure of any of aspects 12-13, wherein the optical coating layer fully or partially fills the plurality of grooves.

Aspect 15. The wafer structure of any of aspects 12-14, wherein the plurality of grooves are in a grid pattern or in a pattern of non-intersecting ellipses.

Aspect 16. The wafer structure of any of aspects 12-15, wherein the optical coating layer has a plurality of depressions corresponding to locations of the plurality of grooves.

Aspect 17. The wafer structure of any of aspects 12-16, wherein the optical coating layer is a niobium-based optical coating layer.

Aspect 18. A method, comprising: cutting a plurality of grooves partially through a thickness of a wafer substrate, wherein the plurality of grooves have a first width; applying an optical coating layer on the wafer substrate and over the plurality of grooves to obtain a wafer structure, wherein dicing streets for the wafer structure align with the plurality of grooves; and dicing the wafer structure along the dicing streets using dicing cuts having a second width less than the first width.

Aspect 19. The method of aspect 18, wherein dicing the wafer structure comprises dicing the wafer structure using a saw having a lesser thickness than the first width of the plurality of grooves.

Aspect 20. The method of any of aspects 18-19, wherein cutting the plurality of grooves comprises: cutting the plurality of grooves to produce abrasions in the wafer substrate having a first surface roughness greater than a second surface roughness of a surface of the wafer substrate.

The foregoing describes only some embodiments, and alterations, modifications, additions and/or changes can be made thereto without departing from the scope and spirit of the disclosed embodiments, the embodiments being illustrative and not restrictive. Furthermore, implementations are not limited to the disclosed embodiments, and may cover various modifications and equivalent arrangements included within the spirit and scope of the disclosed embodiments. Also, the various embodiments described above may be implemented in conjunction with other embodiments, for example, aspects of one embodiment may be combined with aspects of another embodiment to realize yet other embodiments. Further, each independent feature or component of any given assembly or process may constitute an additional embodiment. As used herein, the singular forms of “a,” “an,” and “the” include plural referents unless the context clearly dictates otherwise. In addition, as used herein, the term “or” means “and/or” unless the context clearly dictates otherwise.

What is claimed is:

1. A method, comprising:
cutting a plurality of grooves partially through a thickness of a wafer substrate,
wherein the plurality of grooves have a first width;
applying an optical coating layer on the wafer substrate and over the plurality of grooves to obtain a wafer structure,
wherein dicing streets for the wafer structure align with the plurality of grooves; and
dicing the wafer structure along the dicing streets using dicing cuts having a second width less than the first width.

2. The method of claim 1, wherein dicing the wafer structure comprises:
dicing the wafer structure using a saw having a lesser thickness than the first width of the plurality of grooves.

3. The method of claim 1, wherein cutting the plurality of grooves comprises:
cutting the plurality of grooves to produce abrasions in the wafer substrate having a first surface roughness greater than a second surface roughness of a surface of the wafer substrate.

4. The method of claim 1, wherein applying the optical coating layer comprises:
applying a niobium-based optical coating layer on the wafer substrate and over the plurality of grooves.

5. The method of claim 1, wherein applying the optical coating layer comprises:
applying a layer structure on the wafer substrate by applying a plurality of niobium-based optical coating layers alternating with a plurality of different optical coating layers.

6. The method of claim 1, wherein applying the optical coating layer on the wafer substrate and over the plurality of grooves fully or partially fills the optical coating layer into the plurality of grooves.

7. The method of claim 1, wherein cutting the plurality of grooves comprises cutting the plurality of grooves in a grid pattern or in a pattern of non-intersecting ellipses.

8. The method of claim 1, wherein the wafer structure has a plurality of depressions corresponding to locations of the plurality of grooves.

9. The method of claim 1, wherein dicing the wafer structure produces an optical device in which the optical coating layer exhibits no delamination that extends more than 10 micrometers from an edge of the optical device.

10. A method, comprising:
partially dicing through a thickness of a wafer substrate to define a plurality of dicing lanes in the wafer substrate;
applying, after partially dicing through the thickness of the wafer substrate, an optical coating layer on the wafer substrate to obtain a wafer structure; and
fully dicing the wafer structure along the plurality of dicing lanes.

11. The method of claim 10, wherein partially dicing through the thickness of the wafer substrate uses a first cutting width, and fully dicing the wafer structure uses a second cutting width narrower than the first cutting width.

12. The method of claim 10, wherein partially dicing through the thickness of the wafer substrate comprises:
partially dicing through the thickness of the wafer substrate to produce abrasions in the wafer substrate having a first surface roughness greater than a second surface roughness of a surface of the wafer substrate.

13. The method of claim 10, wherein applying the optical coating layer comprises:
applying a niobium-based optical coating layer on the wafer substrate.

14. The method of claim 10, wherein applying the optical coating layer comprises:
applying a layer structure on the wafer substrate by applying a plurality of niobium-based optical coating layers alternating with a plurality of different optical coating layers.

15. The method of claim 10, wherein fully dicing the wafer structure produces an optical device in which the optical coating layer exhibits no delamination that extends more than 10 micrometers from an edge of the optical device.

16. A method, comprising:
cutting a plurality of grooves partially through a thickness of a wafer substrate;
applying an optical coating layer on the wafer substrate and over the plurality of grooves to obtain a wafer structure; and
dicing the wafer structure along the plurality of grooves.

17. The method of claim 16, wherein the plurality of grooves have a first width that is wider than a second width of dicing cuts used for the wafer structure.

18. The method of claim 16, wherein cutting the plurality of grooves comprises:
cutting the plurality of grooves to produce abrasions in the wafer substrate having a first surface roughness greater than a second surface roughness of a surface of the wafer substrate.

19. The method of claim 16, wherein applying the optical coating layer comprises:
applying a niobium-based optical coating layer on the wafer substrate and over the plurality of grooves.

20. The method of claim 16, wherein dicing the wafer structure produces an optical device in which the optical coating layer exhibits no delamination that extends more than 10 micrometers from an edge of the optical device.
